(19) United States
(12) Patent Application Publication
(10) Pub. No.: US 2006/0098750 A1
(43) Pub. Date: May 11, 2006

(54) Circuit and method for reducing impulse noise

(76) Inventor: Sergey Zhidkov, Suwon-si (KR)

Correspondence Address: HARNESS, DICKEY & PIERCE, P.L.C., P.O. BOX 8910, RESTON, VA, 20195, US

(21) Appl. No.: 11/266,216

(22) Filed: Nov. 4, 2005

(30) Foreign Application Priority Data
Nov. 5, 2004 (KR) 10-2004-0089693

(51) Int. Cl. H03D 1/04; H04K 1/10

(52) U.S. Cl. 375/260; 375/346

(57) ABSTRACT

A circuit and method for reducing impulse noise. The circuit may include a noise measuring unit which determines whether a first logic level or a delayed version of a received signal sample will be output based on a comparison of absolute values of a plurality of delayed versions of the received signal sample. The method may include delaying a received signal to generate a plurality of delayed signals and calculating the absolute value of each of the plurality of delayed signals. The amplitude of the absolute value of one of the plurality of delayed signals may be compared with the amplitudes of the other plurality of delayed signals. An output of a circuit may be set based on the result of the comparison.

### BACKGROUND OF THE INVENTION

This application claims the priority of Korean Patent Application No. 2004-89693, filed on Nov. 5, 2004 in the Korean Intellectual Property Office, the disclosure of which is incorporated herein in its entirety by reference.

1. Field of the Invention

Example embodiments of the present invention relate generally to a circuit and method thereof, and more particularly to a circuit for reducing impulse noise and method thereof.

2. Description of the Related Art

An orthogonal frequency division multiplexing (OFDM) technique may be an example of a multiple carrier modulation (MCM) technique. The OFDM technique may be applied in the field of digital transmission (e.g., digital audio broadcasting (DAB), digital television, wireless local area networks (WLANs), wireless asynchronous transfer mode (WATM) systems, etc.).

In the OFDM technique, data for transmission may be divided into a plurality of segments. Each of the plurality of segments may be modulated and transmitted in parallel. However, the above-described OFDM technique may require complex circuitry. Other conventional types of digital signal processing techniques may include Fast Fourier Transform (FFT) and Inverse FFT (IFFT).

The OFDM technique may be similar to a frequency division multiplexing (FDM) technique. However, in the OFDM technique, each of a plurality of subcarriers may be transmitted in the orthogonal direction with respect to other subcarriers, thereby achieving an increased data transmission efficiency when data is transmitted at higher speeds. Various techniques (e.g., OFDM/time division multiple access (OFDM/TDMA), OFDM/code division multiple access (OFDM/CDMA), etc.) may use the OFDM technique to transmit data at higher speeds.

A MCM signal received with the OFDM technique may experience noise incurred between a transmitter and a receiver. OFDM systems may be less sensitive to noise (e.g., impulse noise interference) as compared to single-carrier systems. Further, the duration of an OFDM symbol may be longer as compared to that of a single-carrier system symbol. Thus, the impulse noise energy may be dispersed throughout each of the OFDM sub-carriers within the symbol duration.

The impulse noise interference may negatively affect the performance of the OFDM system (e.g., a digital video broadcasting-terrestrial (DVB-T) system using 64 quadrature amplitude modulation (QAM)).

A conventional method for reducing impulse noise in OFDM systems may include time-domain clipping.

FIG. 1 is a block diagram illustrating a conventional clipping system 100. Referring to FIG. 1, the clipping system 100 may include a variable gain amplifier 110, a clipping unit 120, an analog-to-digital converter (ADC) 130, a power measuring unit 140 and a threshold calculator 150.

The clipping system 100 may perform clipping in an analog domain (e.g, before an analog signal may be transformed into a digital signal). The clipping system 100 may perform clipping with a fixed threshold clipping value. The required amount of clipping may be determined by measuring the power of a signal received from the ADC 130 and adjusting an amplitude gain of the received signal.

The power measuring unit 140 may measure the power of the signal received from the ADC 130 and may provide the measurement to the threshold calculator 150. The threshold calculator 150 may adjust the amplitude gain of the received signal by controlling the variable gain amplifier 110. The signal with the adjusted amplitude may be received by the clipping unit 120. The clipping unit 120 may clip the signal with the adjusted amplitude. The clipping level at the clipping unit 120 may approximate the peak amplitude of an OFDM signal.

If the amplitude of impulse noise is higher than the mean power of OFDM signals, the clipping method described above with respect to FIG. 1 may reduce impulse noise. Impulse noise peak amplitudes may be replaced with the amplitudes of signal samples which may approximate the peak amplitude of the OFDM signal. However, the clipping method as described above with respect to FIG. 1 may create distortion of the orthogonality of subcarriers which may subsequently increase a bit-error rate (BER).

FIG. 2 illustrates a conventional clipping response. The clipping response of FIG. 2 may be performed in a time domain. The peaks of impulses exceeding a threshold clipping level may be replaced with a second logic level (e.g., a lower logic level or logic “0”). As shown in FIG. 2, peaks of impulses (e.g., of impulse noise exceeding the threshold clipping level (as shown in FIG. 2 (a)) may be replaced with a zero level (as shown in FIG. 2 (b)). In the clipping response illustrated in FIG. 2, clipping may be performed after an ADC operation.

FIG. 3 is a block diagram illustrating a clipping system 300. Referring to FIG. 3, when the clipping system 300 receives an OFDM signal Sₖ, an absolute value measuring unit 301 may measure an absolute value of the OFDM signal Sₖ and a comparator 302 may compare the measured absolute value with a threshold value C that may be used to determine clipping levels. The OFDM signal Sₖ may be a normal signal with a given amount of impulse noise,

The comparator 302 may output a first logic level (e.g., a higher logic level or a logic “1”) when the absolute value is greater than the threshold value C. Alternatively, the comparator 302 may output the second logic level when the absolute value is less than the threshold value C. A selector 303 may output the second logic level when the comparator 302 outputs the first logic level. Alternatively, the selector 303 may output the received OFDM signal Sₖ when the comparator 302 outputs the second logic level. The output of the selector 303 (e.g., the second logic level, the OFDM signal Sₖ, etc.) may be transmitted to an OFDM demodulator 304.

Thus, the clipping system 300 may output the second logic level in place of the OFDM signal Sₖ and may transmit the second logic level to the OFDM demodulator 304 when the absolute value of the OFDM signal Sₖ is greater than the threshold value C. Alternatively, when the absolute value of the OFDM signal Sₖ is less than the threshold value C, the clipping system 300 may transmit the OFDM signal Sₖ to the OFDM demodulator 304.

When the absolute value of the OFDM signal Sₖ is greater than the threshold value C, the OFDM signal Sₖ may include impulse noise. Thus, the above described method of inserting the second logic level in place of the OFDM signal Sₖ when the OFDM signal Sₖ is greater than the threshold value C may reduce the level of received noise within the OFDM signal Sₖ.

The determination of the threshold value C may affect the performance of a receiver executing the clipping method as described above with respect to FIGS. 2 and 3. The threshold value C may be determined based on the characteristics of impulse noise. For example, the threshold value C may be a higher number when the amplitude of the impulse noise is at a higher level. Likewise, the threshold value C may be a lower number when the amplitude of the impulse noise is at a lower level.

The performance of the receiver may also be affected by the characteristics of an automatic gain control (AGC) scheme (e.g., VGA 110 as shown in FIG. 1). If the AGC device sets the threshold value C to a non-desirable level (e.g., the threshold value C may be set to a smaller level as compared to a desired level), additional portions of received OFDM signals (e.g., in addition to portions including impulse noise) may be clipped. Thus, an output of the receiver may not be reliable.

The threshold value C may be set to a higher level (e.g., higher than a desired level) in order to avoid the above-described problem and reduce degradation of the received OFDM signals. For example, the threshold value C may bet set to be 15 dB higher than the average OFDM signal level. However, setting the threshold values to the higher level may increase an amount of noise in the received signals.

### SUMMARY OF THE INVENTION

An example embodiment of the present invention is directed to a circuit, including a noise measuring unit comparing an absolute value of a first signal sample with absolute values of a plurality of second signal samples and generating a rank value based on the results of the comparison.

Another example embodiment of the present invention is directed to a method of reducing impulse noise, including delaying a received signal to generate a plurality of delayed signals, calculating the absolute value of each of the plurality of delayed signals, comparing the calculated absolute amplitude of a first of the plurality of delayed signals with the calculated absolute amplitude of at least one of the other plurality of delayed signals and setting an output based on the comparison.

### BRIEF DESCRIPTION OF THE DRAWINGS

The example embodiments of the present invention will become more apparent by describing in detail example embodiments thereof with reference to the attached drawings in which:

FIG. 1 is a block diagram illustrating a conventional clipping system.

FIG. 2 illustrates a conventional clipping response.

FIG. 3 is a block diagram illustrating a clipping system.

FIG. 4 illustrates a circuit according to an example embodiment of the present invention.

FIG. 5 illustrates a series of signal samples received by the circuit of FIG. 4 according to another example embodiment of the present invention

FIG. 6 is a circuit diagram of a circuit and a demodulator according to another example embodiment of the present invention.

FIG. 7 is a block diagram illustrating an orthogonal frequency division multiplexing (OFDM) transmitting and receiving system according to another example embodiment of the present invention.

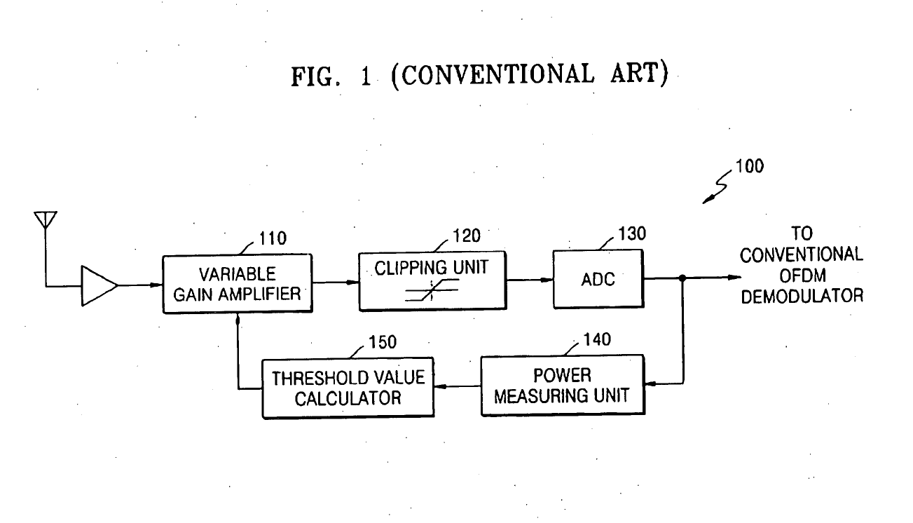

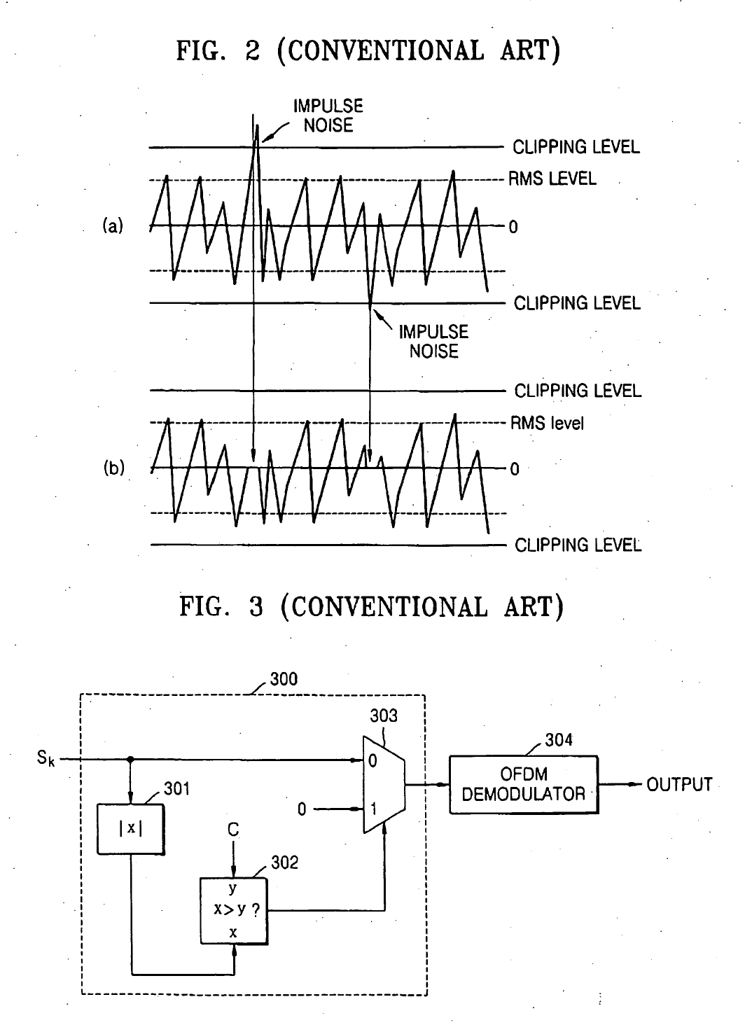

### DETAILED DESCRIPTION OF THE EXAMPLE EMBODIMENTS OF THE PRESENT INVENTION

Hereinafter, example embodiments of the present invention will be described in detail with reference to the accompanying drawings.

In the Figures, the same reference numerals are used to denote the same elements throughout the drawings.

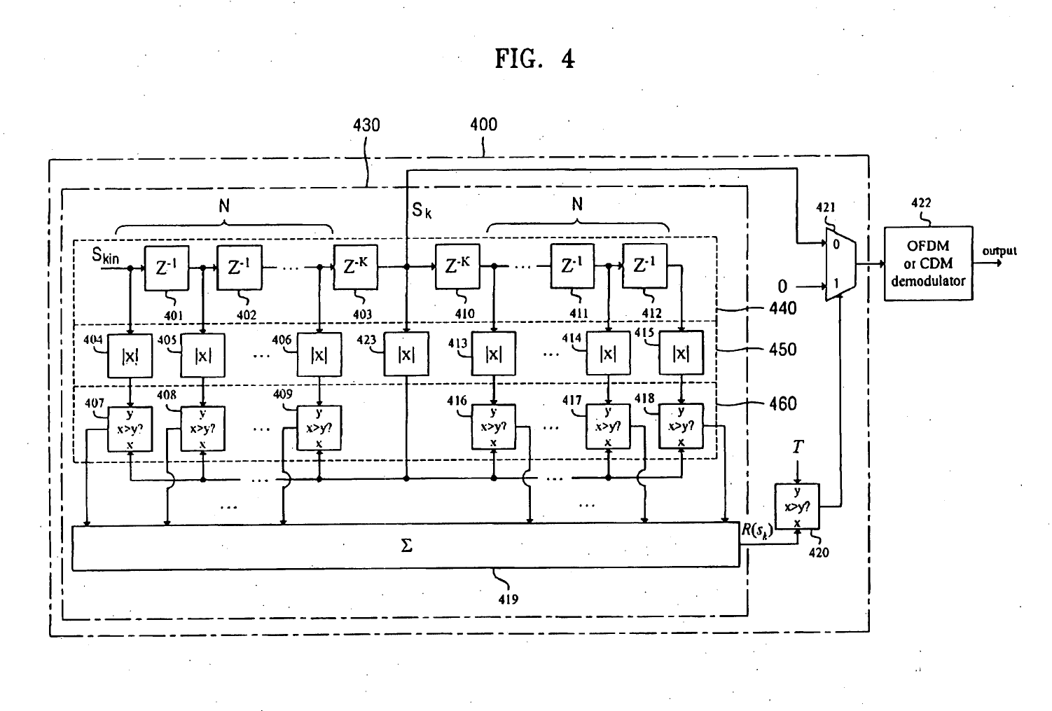

FIG. 4 illustrates a circuit 400 according to an example embodiment of the present invention. In the example embodiment of FIG. 4, the circuit 400 may include a threshold comparator 420, a selector 421 and a noise measuring unit 430. The circuit 400 may output a signal to a demodulator 422. The circuit 400 may reduce noise associated with a received signal sample (e.g., a multiple carrier modulation (MCM) signal).

In the example embodiment of FIG. 4, the noise measuring unit 430 may compare an absolute value of a signal sample Sₖ with the absolute values of a plurality of samples (e.g., obtained by delaying an input MCM signal sample Sₖᵢₙ). The noise measuring unit 430 may combine the results of the comparison. The noise measuring unit 430 may generate a rank value R(Sₖ) based on the combined results.

The received signal will hereinafter be referred to as including at least one of an OFDM signal and a code division multiplexing (CDM) signal. However, it is understood that, in other example embodiments, the received signal may include any type of signal capable of modulation. Likewise, the circuit 400 may be configured to process OFDM signals, CDM signals and/or other types of signals.

In the example embodiment of FIG. 4, the threshold comparator 420 may compare the rank value R(Sₖ) with a threshold T and may generate a selection signal based on a result of comparison. The selector 421 may output one of the current signal sample Sₖ or a second logic level (e.g., a lower logic level or “0”) in response to the selection signal.

In the example embodiment of FIG. 4, the circuit 400 may reduce impulse noise in a processed signal (e.g., a OFDM signal, a CDM signal, etc.). The circuit 400 may detect signal samples influenced by impulse noise in order to reduce performance degradation in a device (e.g., an amplitude gain control (AGC)) operating with a non-optimal clipping threshold. The amplitudes of signal samples influenced by impulse noise may be higher as compared to neighboring signal samples not influenced by impulse noise. The probability that a given signal sample is influenced by impulse noise may be proportional to a given number of neighboring signal samples with lower amplitudes as compared to the given signal sample. The given number may indicate the rank of the given signal sample. Characteristics of rank-based detectors (e.g., circuit 400) need not depend on a signal level and/or signal distribution to ensure correct operation.

In the example embodiment of FIG, 4, circuit 400 may use the rank of a signal sample Sₖ to detect signal samples affected by impulse noise. The circuit 400 may compute a rank value R(Sₖ) of the signal sample Sₖ as given by

$$R ( {S}_{k} ) = {\sum }_{i = N … N ; i \neq k} h ( \vert {S}_{k} \vert - \vert {S}_{k + i} \vert ) \qquad Equation 1$$

where h(x)=1 . . . x>0=0 . . . x≦0

In the example embodiment of FIG. 4, the rank value R(Sₖ) may be computed by the noise measuring unit 430 using Equation 1. The noise measuring unit 430 may include a delay line 440, an absolute value calculating unit 450, a comparing unit 460 and an adder 419.

The delay line 440 may include a plurality of delayers 401/402/403/410/411/412 connected in series. Each of the delayers 401/402/403/410/411/412 may delay the signal sample Sₖᵢₙ and may output the delayed result. As shown in FIG. 4, the signal sample Sₖ may be an intermediate signal sample of signal samples obtained by delaying the signal sample Sₖᵢₙ.

In an example, an output of the delayer 403 may be located near the center of the delay line 440. The output may be the signal sample Sₖ. The signal sample Sₖᵢₙ may be a base-band signal including a value (e.g., a real number or a complex number) received from an analog-to-digital converter (ADC) (not shown).

In the example embodiment of FIG. 4, the absolute calculating unit 450 may compute the amplitudes (e.g., the absolute value of amplitudes) of signal samples received from the delay line 440 using a plurality of absolute calculators 404/405/406/413/414/415/423. The absolute value calculating unit 450 may output the absolute values of the delayed signal samples from the delayers 401/402/403/410/411/412 at the absolute calculators 404/405/406/413/414/415, respectively. The absolute value calculating unit 450 may output the absolute value of the signal sample Sₖ at the absolute calculator 423.

The comparing unit 460 may compare the absolute value of the signal sample Sₖ (e.g., from the absolute calculator 423) with the absolute values received from the absolute calculators 404/405/406/413/414/415 at a plurality of comparators 407/408/409/416/417/418, respectively. The comparators 407/408/409/416/417/418 may output a first logic level (e.g., a higher logic level or logic “1”) when the absolute value of the signal sample Sₖ is higher than the compared output from the absolute value calculator 450 (e.g., from each of the absolute calculators 404/405/406/413/414/415). Otherwise, the comparators (407/408/409/416/417/418) may output a second logic level (e.g., a lower logic level or logic “0”).

The adder 419 may receive the results of each of the comparisons of the comparing unit 460 (e.g., the outputs of each of the comparators 407/408/409/416/417/418). The adder 419 may combine the received comparison results from the comparing unit 460 and may output the rank value R(Sₖ) (e.g., the number of comparators outputting the first logic level).

The absolute calculating unit 450 may not calculate absolute values of K (e.g., where K may be a natural number) outputs of the delayer 403 obtained before the signal sample Sₖ is generated and K outputs of the delayer 410 obtained after the signal sample Sₖ is generated. Impulse noise may influence a series of signal samples (e.g., consecutive or neighboring signal samples), and the impulse noise influence may not be limited to a single signal sample. Thus, by not calculating absolute values for K signal samples received before and/or after the signal sample Sₖ, an efficiency of the circuit 400 may increase (e.g., because signals with a higher probability of having a higher impulse noise levels may not require the calculation).

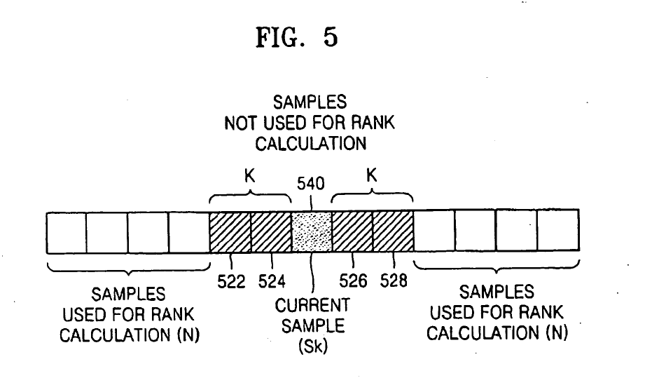

FIG. 5 illustrates a series of signal samples received by the circuit 400 of FIG. 4 according to another example embodiment of the present invention

In an example, if all of the signal samples adjacent (e.g., neighboring or in close proximity) to the signal sample Sₖ are affected by impulse noise, the amplitudes of the affected signal samples may be higher as compared to the amplitude of the signal sample Sₖ. In this example, as shown in FIG. 5, the K (e.g., in the example of FIG. 5, K may be equal to two) signal samples 522/524 obtained before the generation of the signal sample Sₖ and the K signal samples 526/528 obtained after the generation of the signal sample Sₖ may be excluded from the calculation of the rank value R(Sₖ).

The rank value R(Sₖ) of the signal sample Sₖ may be compared with the threshold T. If the rank value R(Sₖ) is higher than a threshold T, the amplitude of the signal sample Sₖ may be replaced with the second logic level. Alternatively, if the rank value R(Sₖ) is less than the threshold T, the signal sample Sₖ may be output.

The above-described example comparison and selection of one of the second logic level and the signal sample Sₖ may be performed by the threshold comparator 420 and the selector 421. The threshold comparator 420 may compare the rank value R(Sₖ) and the threshold T and may generate a selection signal (e.g., the result of the comparison). The threshold T may be a reference value used to clip noise in a received signal. The threshold T may be set to a higher value (e.g., a level sufficient to reject impulse noise without degrading the integrity of received signal samples).

The selection signal received from the threshold comparator 420 may be set to the first logic level (e.g., one of a higher and lower logic level) when the rank value R(Sₖ) is greater than the threshold T. The selection signal received from the threshold comparator 420 may be set to the second logic level (when the rank value R(Sₖ) is less than the threshold T. The selector 421 may output either the signal sample Sₖ or the second logic level based on the selection signal. If the selection signal is at the first logic level, the selector 421 may output the second logic level. If the selection signal is at the second logic level, the selector 421 may output the signal sample Sₖ.

The output of the selector 421 (e.g., one of the signal sample Sₖ and the second logic level) may be sent to the demodulator 422. The demodulator 422 may decode the received output from the selector 421 and may generate a bit stream. The demodulator 422 may be any well-known demodulator (e.g., an OFDM demodulator, a CDM demodulator, etc.).

In the example embodiment of FIG. 4, the circuit 400 may be capable of determining a clipping level (e.g., the threshold T) which may be used for rejecting impulse noise irrespective of the amplitude and/or distribution of the signal sample Sₖᵢₙ.

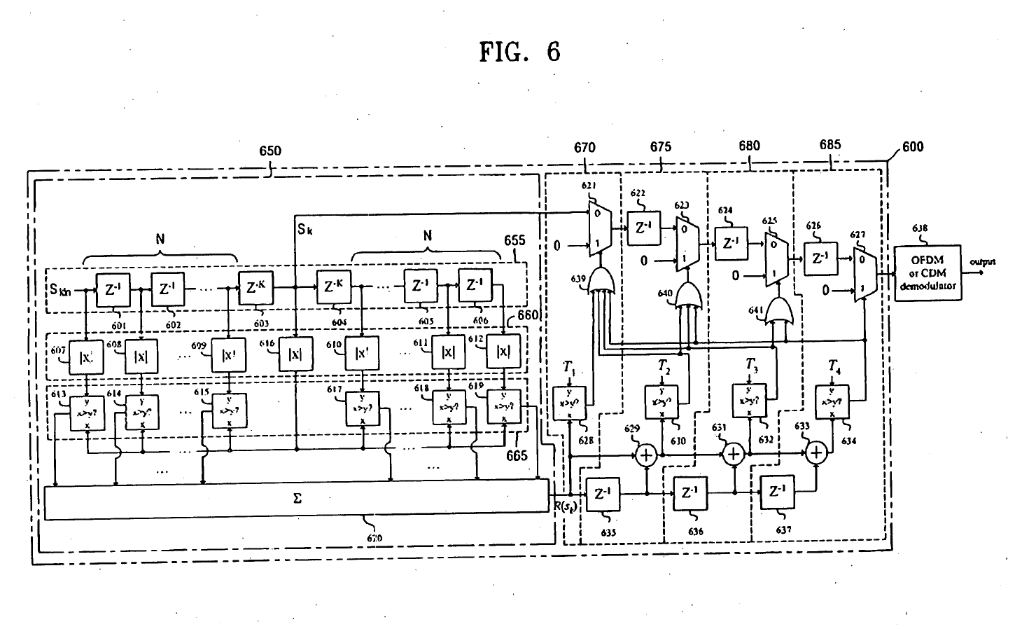

FIG. 6 is a circuit diagram of a circuit 600 and a demodulator 638 according to another example embodiment of the present invention. The circuit 600 may include a noise measuring unit 650, a clipping controller 670 and sub clipping controllers 675, 680/685.

In the example embodiment of FIG. 6, the circuit 600 may detect isolated signal samples affected by impulse noise as well as groups of signal samples affected by an impulse noise burst.

In the example embodiment of FIG. 6, if a rank value R(Sₖ) of the signal sample Sₖ is higher than a first threshold T1 (i.e., R(Sₖ)>T1), the amplitude of the signal sample Sₖ may be set to the second logic level. The rank value R(Sₖ) of the signal sample Sₖ may be calculated by the noise measuring unit 650. The noise measuring unit 650 of the circuit 600 may function similarly to the noise measuring unit 430 of the circuit 400 and will not be described further for the sake of brevity.

The clipping controller 670 may compare the rank value R(Sₖ) of the signal sample Sₖ with the first threshold T1. The clipping controller 670 may output the signal sample Sₖ if the rank value R(Sₖ) is less than the first threshold T1. Alternatively, the clipping controller 670 may output the second logic level when the rank value R(Sₖ) is greater than the first threshold T1. The clipping controller 670 may include a threshold comparator 628, an OR operation unit 639 and a selector 621.

The threshold comparator 628 may compare the rank value R(Sₖ) with the first threshold T1. The threshold comparator 628 may generate a selection signal based on the comparison result. The OR operation unit 639 may perform an OR operation on the selection signal and a plurality of sub selection signals. The selector 621 may output the one of the signal sample Sₖ and the second logic level in response to the output from the OR operation unit 639.

The selection signal may be set to the first logic level (e.g., one of a higher logic level and a lower logic level) if the rank value R(Sₖ) is higher than the first threshold T1. If the selection signal is at the first logic level, the selector 621 may output the second logic level. Alternatively, the selection signal may be set to the second logic level (e.g., one of a higher logic level and a lower logic level) if the rank value R(Sₖ) is less than the first threshold T1. If the selection signal is at the second logic level, the selector 621 may output the signal sample Sₖ. If at least one of the plurality of sub selection signals is at the first logic level, the selector 621 may output the second logic level.

In the example embodiment of FIG. 6, the function of the noise measuring unit 650 and the clipping controller 670 may be similar to the above-described function of the circuit 400 of FIG. 4. However, when the sum of the rank value R(Sₖ) of the signal sample Sₖ and a rank value R(Sₖ₋₁) of a previous signal sample Sₖ₋₁ is greater than a second threshold T2 (i.e., R(Sₖ)+R(Sₖ₋₁)>T2), the circuit 600 may set both the amplitudes of the current and previous signal samples Sₖ and Sₖ₋₁ to the second logic level with the sub clipping controllers 675, 680 and 685.

The sub clipping controllers 675, 680, and 685 may be connected in series with the clipping controller 670. Each of the sub clipping controllers 675, 680 and 685 may output the signal sample from their respective preceding element (e.g., the clipping controller 670, the sub clipping controller 675, or the sub clipping controller 680) of the sub clipping controllers 675, 680 and 685, respectively, if the sum of the rank value received from the preceding element and a value obtained by delaying the rank value is less than the threshold value T2. Alternatively, if the above-described conditions are not met, the sub clipping controllers 675, 680 and/or 685 may output the second logic level.

In the example embodiment of FIG. 6, the sub clipping controller 675 may include a first sub delayer 635, a sub adder 629, a sub threshold comparator 630, a sub OR operation units 640, a second sub delayer 622 and a sub selector 623. The sub clipping controller 680 may include a first sub delayer 636, a sub adder 631, a sub threshold comparator 632, a sub OR operation unit 641, a second sub delayer 624 and a sub selector 625. The sub clipping controller 685 may include a first sub delayer 637, a sub adder 633, a sub threshold comparator 634, a second sub delayer 626 and a sub selector 627.

The first sub delayers 635, 636 and 637 may delay the rank values output from the clipping controller 670, the sub clipping controller 675, and the sub clipping controller 680, respectively. The sub adders 629, 631, and 633 may combine the rank values received outputs from the clipping controller 670, the sub clipping controller 675, and the sub clipping controller 680, respectively, and the outputs received from the first delayers 635, 636, and 637, respectively.

The sub threshold comparators 630, 632, and 634 may compare outputs received from the sub adders 629, 631 and 633 and their corresponding thresholds T2, T3, and T4, respectively, thereby generating a sub selection signal for each of the sub threshold comparators 630, 632 and 634. The sub OR operation unit 640 may perform an OR operation on the sub selection signal received from the sub clipping controller 675 and the sub selection signal received from the sub clipping controller 680. The sub OR operation unit 641 may perform an OR operation on the sub selection signal received from the sub clipping controller 680 and the sub selection signal received from the sub clipping controller 685.

The second sub delayers 622, 624 and 626 may delay the outputs of the selector 621 (from the clipping controller 670), the sub selector 623 (from the sub clipping controller 675), and the sub selector 625 (from the sub clipping controller 680), respectively, and may output the delayed outputs. The sub selectors 623, 625, and 627 may output one of the outputs of the second sub delayers 622, 624 and 626 and the second logic level based on the outputs (e.g., selection signals) received from the sub OR operation units 640 and 641.

The sub selection signal may be set to the first logic level if the outputs of the sub adders 629, 631 and 633 are higher than their corresponding thresholds T2, T3, and T4, respectively. Otherwise, the sub selection signal may be set to the second logic level. If the sub selection signal is set to the second logic level, the sub selectors 623, 625, and 627 and the selector 621 may output the second logic level. Alternatively, if the sub selection signal is at the first logic level, the sub selectors 623, 625, and 627 may output the outputs received from the second sub delayers 622, 624 and 626, respectively.

As described above and shown in FIG. 6, the circuit 600 may include one clipping controller 670 and three sub clipping controllers 675, 680 and 685. Accordingly, the above-described example circuit 600 may be capable of detecting the impulse noise burst which may affect a series of four signal samples. The circuit 600 may adjust the amplitude of the detected signal samples.

However, the number of sub clipping controllers included within the circuit 600 according to other example embodiments of the present invention is not limited to the above-described and illustrated numbers. Rather, the number of clipping controller and sub clipping controllers may scale (e.g., based on application specific requirements).

In another example embodiment of the present invention, the thresholds T₁-T₄ may be set so as to satisfy the relationship as given by

$${T}_{1} \geq \frac{{T}_{2}}{2} \geq \frac{{T}_{3}}{3} \geq \frac{{T}_{4}}{4} … \qquad Equation 2$$

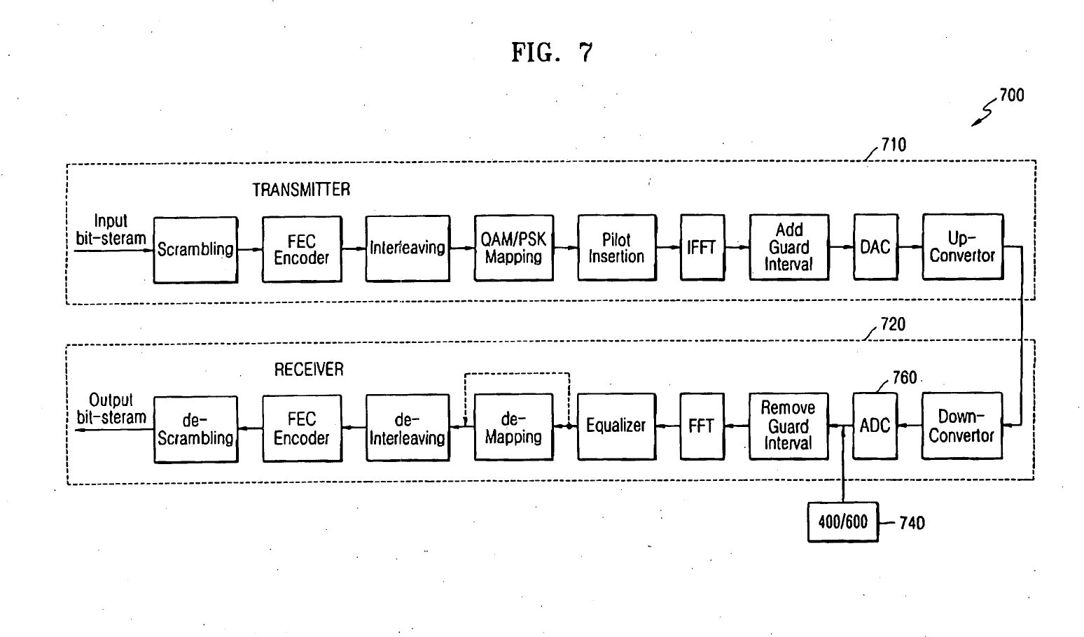

FIG. 7 is a block diagram illustrating an OFDM transmitting and receiving system 700 (hereinafter referred to as the “system 700”) according to another example embodiment of the present invention. The system 700 may include the circuit 400 of FIG. 4 or the circuit 600 of FIG. 6 (e.g., in position 740). The system 700 may include a transmitting system 710 and a receiving system 720. The position 740 (e.g., including the circuit 400/600) may be installed next to an ADC 760 of the receiving system 720. In other words, a signal sample Sₖᵢₙ may be received at the position 740 from the ADC 760.

While the above-described example embodiments and associated figures have been described and illustrated with respect to hardware implementations, it will be appreciated that, in other example embodiments, the above-described functionality may be achieved with other methodologies (e.g., a software system).

The example embodiments of the present invention being thus described, it will be obvious that the same may be varied in many ways. For example, it is understood that the above-described first and second logic levels may correspond to higher and lower logic levels, respectively, or, alternatively, to lower and higher logic levels, respectively. Further, it is understood that the first and second logic levels may correspond to analog voltages (e.g, in the analog domain) or numeric representations (e.g., “0” or “1”) (e.g., in the digital domain).

Such variations are not to be regarded as departure from the spirit and scope of the example embodiments of the present invention, and all such modifications as would be obvious to one skilled in the art are intended to be included within the scope of the following claims.

What is claimed is:

1. A circuit, comprising:
a noise measuring unit comparing an absolute value of a first signal sample with absolute values of a plurality of second signal samples and generating a rank value based on the results of the comparison.

2. The circuit of claim 1, further comprising:
a threshold comparator comparing the rank value with a rank value threshold and generating a selection signal based on the comparison; and
a selector outputting an output signal based on the selection signal.

3. The circuit of claim 2, wherein the selection signal is at a first logic level if the rank value is greater than the rank value threshold and the selection signal is at a second logic level if the rank value is less than or equal to the rank value threshold.

4. The circuit of claim 2, wherein the output signal is at a first logic level if the selection signal is at a first selection level and the output signal is the first signal sample if the selection signal is at a second selection level.

5. The circuit of claim 4, wherein the first logic level is a low logic level.

6. The circuit of claim 2, wherein the output signal is one of the first signal sample and a first logic level.

7. The circuit of claim 6, wherein the first logic level is a low logic level.

8. The circuit of claim 2, wherein the rank value threshold is used to clip noise.

9. The circuit of claim 1, wherein the first signal sample is a multiple carrier modulation (MCM) signal sample.

10. The circuit of claim 8, wherein the MCM signal sample is one of an orthogonal frequency division multiplexing (OFDM) signal and a code division multiplexing (CDM) signal.

11. The circuit of claim 1, wherein the first signal sample is an intermediate sample of the plurality of second signal samples.

12. The circuit of claim 1, wherein the plurality of second signal samples are generated by delaying a received signal sample.

13. The circuit of claim 1, wherein the noise measuring unit includes:
a delay line having a plurality of delayers connected in series, each of the plurality of delayers delaying a received signal sample and outputting one of the first signal sample and one of the plurality of second signal samples, the plurality of delayers including an intermediate delayer outputting the first signal sample;
an absolute value calculator outputting absolute values of the plurality of second signal samples, the first signal sample and the received signal sample to the plurality of comparators; and
a plurality of comparators performing comparisons, each of the plurality of comparators outputting a first logic level if the absolute value of the amplitude of the first signal sample is greater than the absolute value of the compared second signal sample and outputting a second logic level if the absolute value of the amplitude of the first signal sample is not greater than the absolute value of the compared second signal sample; and
an adder combining the results of the comparisons and outputting the rank value.

14. The circuit of claim 13, wherein the rank value is not affected by the outputs of K delayers preceding the first signal sample and the outputs of K delayers following the first signal sample, K being a natural number.

15. The circuit of claim 13, wherein the rank value is a number of the comparison outputs at the first logic level.

16. The circuit of claim 13 wherein the first logic level is one of a higher and a lower logic level.

17. The circuit of claim 13, wherein the second logic level is one of a higher and a lower logic level.

18. The circuit of claim 1, wherein the first signal sample and the plurality of second signal samples are delayed portions of a received signal sample.

19. The circuit of claim 18, wherein the received signal sample is a base-band signal.

20. The circuit of claim 18, wherein the received signal sample is received from an analog-to-digital converter.

21. The circuit of claim 18, wherein a value of the received signal sample is one of a real and a complex value.

22. The circuit of claim 2, further comprising:
a clipping controller including the threshold comparator; and
a plurality of sub clipping controllers connected to the clipping controller in series, each of the plurality of sub clipping controllers comparing a current rank value with at least one delayed rank value, each of the plurality of sub clipping controllers outputting a received signal sample if a sum of the current rank value and the at least one delayed rank value is less than or equal to a sub comparator threshold and outputting a first logic level if the sum is greater than the sub comparator threshold.

23. The circuit of claim 22, wherein the current rank value is the generated rank value.

24. The circuit of claim 22, wherein the delayed rank value is associated with a previously received signal sample.

25. The circuit of claim 22, wherein each of the sub clipping controllers includes:
a sub threshold comparator performing the comparison;
a sub selector outputting one of the first signal sample and an output signal at the first logic level in response to a sub selection signal.

26. The circuit of claim 25, wherein the sub selection signal is the result of the comparison.

27. The circuit of claim 25, wherein the sub selection signal is the result of an OR operation unit performed on the result of the comparison and at least one result of a comparison from at least one other sub clipping controller.

28. The circuit of claim 22, wherein at least one of the plurality of sub clipping controllers includes:
a first sub delayer delaying a received rank value;
a sub adder computing the sum of the current rank value and the delayed rank value;
a sub threshold comparator comparing an output of the sub adder and the sub comparator threshold and generating a sub selection signal;
a sub OR operation unit performing an OR operation on the sub selection signal and sub selection signals received from at least one other of the plurality of sub clipping controllers;
a second sub delayer delaying one of the outputs of a selector of the clipping controller and an output of a sub selector of one of the plurality of sub clipping controllers, the second sub delayer outputting a resultant second sub delayed signal, the sub selector outputting one of an output signal of the second sub delayer and an output signal at a first logic level in response to an output of the sub OR operation unit,
wherein the sub selection signal level is at a first level when the output of the sub adder is greater than the sub comparator threshold and is at a second level when the output of the sub adder is not greater than the sub comparator threshold.

29. The circuit of claim 28, wherein the sub selector outputs a signal at the first logic level if the sub selection signal is at the first level and the sub selector outputs the output of the second sub delayer if the sub selection signal is at the second level.

30. The circuit of claim 22, wherein the plurality of sub clipping controllers include at least three sub clipping controllers.

31. A method of reducing impulse noise, comprising:
delaying a received signal to generate a plurality of delayed signals;
calculating the absolute value of each of the plurality of delayed signals;
comparing the calculated absolute amplitude of a first of the plurality of delayed signals with the calculated absolute amplitude of at least one of the other plurality of delayed signals; and
setting an output based on the comparison.

32. The method of claim 31, wherein the output is a first logic level if a given number of comparisons indicate the first delayed signal includes a greater calculated absolute amplitude than the compared one of the other plurality of delayed signals.

33. The method of claim 31, wherein the output is the first of the plurality of delayed signals if a given number of comparisons do not indicate the first delayed signal does not include a greater calculated absolute amplitude than the compared one of the other plurality of delayed signals.

34. The method of claim 31, wherein the comparison affects at least one additional comparison of at least one subsequently received signal.

35. The method of claim 31, wherein the output is further based on an at least one earlier comparison of at least one previously received signal.

36. The method of claim 35, further comprising:
clipping at least one signal portion based on the comparisons.

37. The method of claim 36, wherein the output is one of a signal including the rank value, the first delayed signal and a signal at a first logic level.

38. A circuit for performing the method of claim 31.
